(19) United States
(12) Patent Application Publication
(10) Pub. No.: US 2008/0313696 A1
(43) Pub. Date: Dec. 18, 2008

(54) Thermal Pad Controlled Equalizer

(76) Inventor: Robert M. Blumenkranz, Brea, CA (US)

Correspondence Address: SoCAL IP LAW GROUP LLP, 310 N. WESTLAKE BLVD. STE 120, WESTLAKE VILLAGE, CA, 91362, US

(21) Appl. No.: 11/761,733

(22) Filed: Jun. 12, 2007

(51) Int. Cl. H04B 3/14; H03G 3/20

(52) U.S. Cl. 725/149; 330/304; 333/18; 333/28 R

(57) ABSTRACT

A thermal pad controlled equalizer that adjusts the slope and gain of an amplifier in response to changes in ambient temperature, effectively simulating automatic gain control. The equalizer has a slope pad and a gain pad. The slope pad increases the attenuation of the signal in response to increases in ambient temperature. The gain pad decreases the attenuation when ambient temperature increases. Thus, the slope and gain pads together compensate for temperature effects on the system.

### BACKGROUND OF THE INVENTION

1. Field of the Invention

The present invention relates the field of signal transmission, especially to the use of equalizers on a coaxial cable transmission system.

2. Description of the Related Art

Coaxial cable transmission systems are used widely for the distribution and transmission of cable television and broadband communications signals. All coaxial cables have a specific amount of dielectric and resistance loss that designers must consider during design and construction of the distribution system. Changes in these parameters after the system is operating may affect the performance of the system severely.

Coaxial cable systems are relatively long, and over long distances these resistive and dielectric losses cause signal attenuation. This attenuation is dependent on cable length and typically is measured in dB. Therefore, the industry commonly refers to attenuation as electrical length. This signal attenuation is non-linear and greatest at the high frequency end of the bandwidth, and decreases as frequency decreases. This result may be referred to as “slope loss.”

Prior art systems use combinations of amplifiers and equalizers spaced throughout the coaxial cable network to compensate for the attenuation and slope loss. The goal is to maintain signal strength and balance throughout the cable network. Each system needs different amplifiers and equalizers depending upon the location within the network. Testing each location is important to determine proper equalization characteristics for that location.

To address these issues, amplifier manufacturers typically produce a range of equalizers with different equalization characteristics. Technicians test the signal strength and slope at particular locations, and select and install the appropriate amplifiers and equalizers for each location. Dan, U.S. Pat. No. 7,039,942 (2006), discusses the problems associated with this method. Prior art methods have attempted to minimize these problems by developing standard equalizer circuits that plug-in components can modify.

The coaxial cable for most systems is above ground where the cable is exposed to ambient conditions. The temperature and weather in some geographic areas are fairly constant throughout the year and between day and night. However, temperature and weather elsewhere vary drastically elsewhere. For example, San Francisco, Calif., has a mean daily maximum temperature in January of 13.1° C. (59° F.) (conversions are approximate), but in the warmest month, August, it is 23.1° C. (74° F.), about a 10° C. (18° F.) difference. Moreover, the difference between the mean daily maximum and minimum is usually less than 10° C. (18° F.). In Chicago, Ill., however, the mean daily maximum temperature in January is −1.7° C. (29° F.), but in the July, the warmest month, it is 28.1° C. (83° F.), more than a 30° C. (54° F.) difference. In addition, the difference between the mean daily maximum and minimum is usually more than 10° C. (18° F.).

Changes in ambient temperature affect the resistive and dielectric properties of co-axial cable, which causes an increase or decrease in the attenuation and electrical length of coaxial cable. Over the long cables used in these networks, these changes substantially affect the overall system performance.

To provide compensation for these changes in electrical length of the coaxial cable, prior art methods add costly automatic gain control circuits within the amplifier. Alternatively, technicians check network amplifiers and equalizers at their various locations throughout the network, obtain new measurements of the signal strength, and change the equalizer circuits or the plug-in components to account for the change in conditions. This method is costly and usually is not feasible. The weather is too unpredictable and technicians would have to make frequent adjustments. Therefore, an equalizer that can respond and compensate for changes in temperature would improve overall system performance without increasing costs significantly.

### SUMMARY OF THE INVENTION

The present invention provides a temperature controlled pad for use with a pad controllable equalizer, thereby eliminating the need to physically install different fixed pads to achieve the desired slope characteristics. By “pad,” applicant means a circuit element that attenuates the signal. Thus, the invention provides automatic slope compensation for cable length

The invention uses a thermal pad that automatically varies the pad value depending upon temperature changes while maintaining or, at minimum, approaching a 75 Ω return loss match for the purpose of impedance matching and achieving a linear response. The changes in pad values adjust the equalization characteristics of the amplifier circuit, providing the necessary compensation to simulate automatic gain control for the effects of temperature. This reduces or eliminates the need for additional automatic gain control circuits, and eliminates the need to change the pad values manually to compensate for temperature changes.

The present invention contemplates the use of two wide-range thermal pads in conjunction with an equalization phasing circuit. One thermal pad is configured to increase the pad attenuation with a corresponding increase in ambient temperature. Another thermal pad would be configured to decrease pad attenuation as temperature increases, operating in an inverse direction with temperature changes. The two thermal pads and equalization phasing circuit are located in series with the signal being transmitted on the cable network and provide compensation for changes in temperature.

### BRIEF DESCRIPTION OF THE DRAWINGS

FIG. 1 is a block diagram of a typical line extender amplifier to be used in a cable network using the present invention.

FIG. 2 is a block diagram of a typical amplification stage.

FIG. 3 is a block diagram of a typical amplification stage that uses a pad controlled or pad adjustable equalizer.

FIG. 4 is a schematic drawing of the overall pad controlled equalizer circuit for use with the present invention.

FIG. 5 is a schematic drawing of a typical thermally controlled slope pad in accordance with the present invention.

FIG. 6 is a schematic drawing of a typical thermally controlled gain pad in accordance with the present invention.

FIG. 7 contains bode gain plots illustrating functionality of the present invention.

FIG. 8 is a printed circuit board (PCB) layout of the thermally controlled pad equalizer.

### DETAILED DESCRIPTION OF THE EXEMPLARY EMBODIMENT

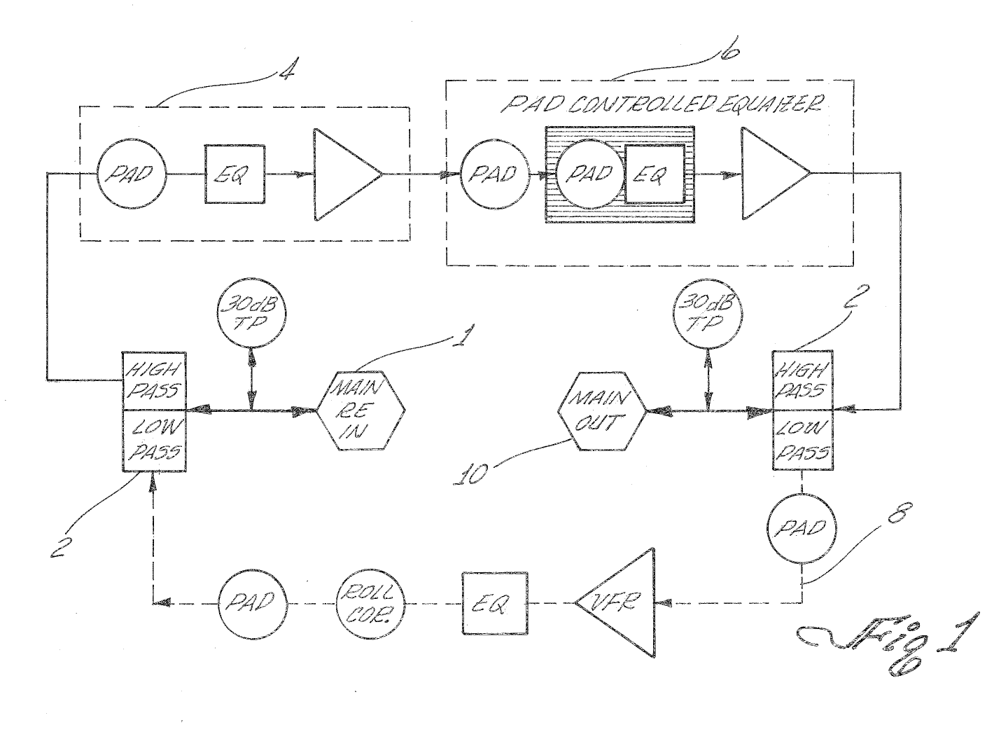

FIG. 1 shows a typical amplifier circuit for use in a cable network. An amplifier or “line extender” with circuitry similar to that shown can be placed at predetermined certain location along the cable transmission network, into the transmission network to compensate for transmission losses.

The input 1 to the amplifier is at the left side of FIG. 1. For this illustration, the direction of forward (downstream to the end user) signal propagation is from left to right in FIG. 1 from the amplifier input 1 to the amplifier output 10. FIG. 1 illustrates a typical amplifier for use in a cable network that is transmitting multiple signals, such as television (regular and high definition) and Internet frequency signals. When transmitting Internet signals, or other two-way signals, the amplifier also receives signals at the amplifier output 10 to be transmitted upstream through a different amplification circuit on a return path 8 to be received upstream at the amplifier input 1. The application discusses forward transmission for the purposes of illustration.

Diplex filters 2 ensure that all forward signals pass through amplification stages 4 and 6 in the forward direction and that any return signals travel along return path 8.

The input signal typically passes through an amplification stage 4. Depending on the particular application needs, a second amplification stage 6 may be present. The second stage in this illustration uses a pad controlled equalizer design. The first amplification stage can 4 function as a preamplifier followed by a second amplification stage 6.

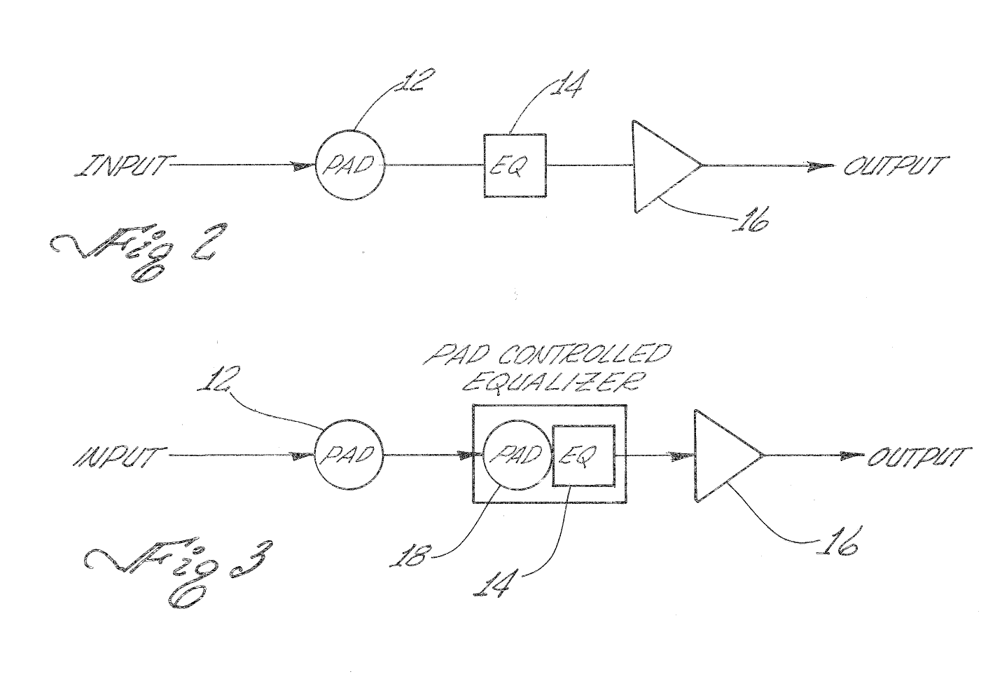

FIG. 2 shows further detail of the typical amplification stage design 4. An input signal is applied to a plug-in attenuation circuit or pad circuit 12. The output of this pad circuit 12 connects in series to an equalization circuit or equalizer 14. Amplifier 16 amplifies the signal from the equalizer output.

This arrangement is representative of typical forward amplifiers in use for cable transmission. The pad circuit 12 of a typical forward amplifier attenuates the signal to adjust the amplifier signal level across the signal bandwidth (commonly referred to as “flat gain” or “flat loss”). The pad circuit 12 typically plugs into the amplifier's circuit board. The plug-in circuit can be removed and replaced with a different plug-in attenuation circuit depending on the particular needs of the application. The pad circuit 12 typically has three pins, an input pin, an output pin, and a ground pin.

The equalizer or equalization circuit 14 (FIG. 2) then equalizes the slope of the signal across the signal bandwidth to compensate for the attenuation characteristics of the cable transmission network with respect to frequency. Generally, the equalizer or equalization circuit will have a frequency response that is opposite the frequency response of the cable preceding the amplifier. This will result in a flat response across frequency when the frequency response characteristics of the cable and the equalizer are combined.

Then amplifier 16 amplifies the signal. Typically cable transmission networks use hybrid amplifiers. However, the type of amplifier chosen is not important to the present invention's functionality. In this type of amplifier design, equalizer 14 controls the slope of the signal at the amplifier 16 output relative to the input signal applied to the pad circuit 12, and changing the pad circuit 12 adjusts the gain.

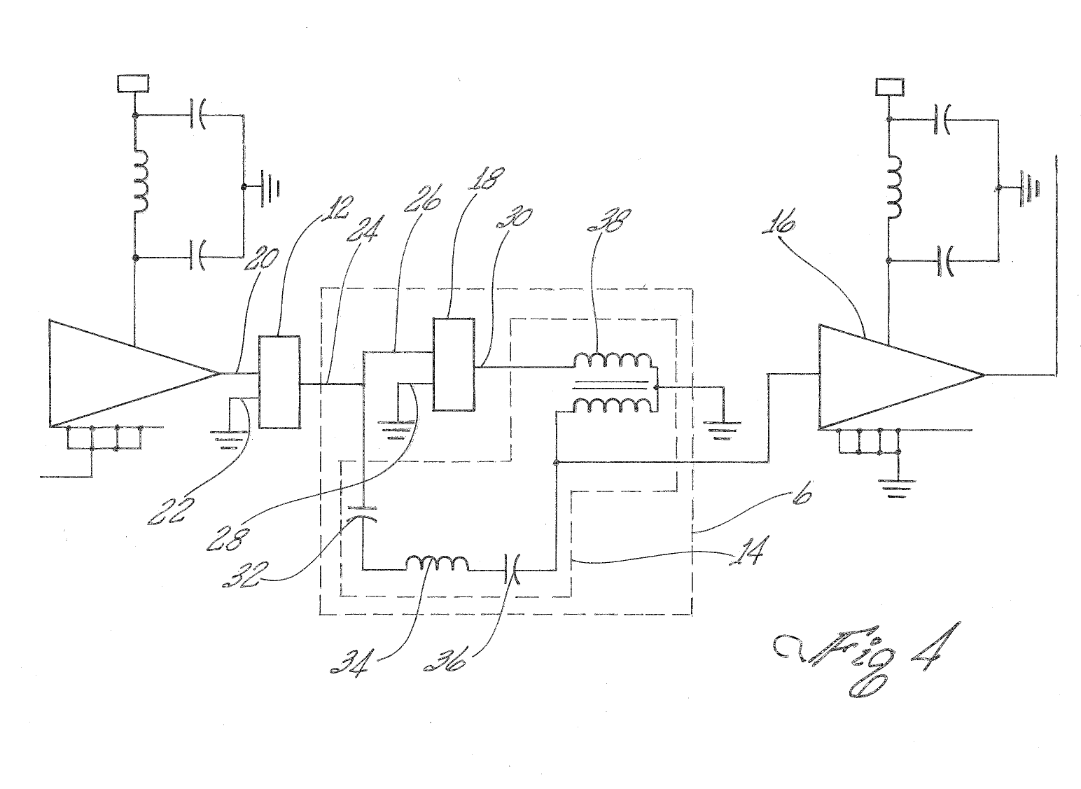

By using an additional plug-in attenuation circuit or slope pad 18 with the FIG. 3 equalization circuit 14, pad controlled equalizer 6 adjusts the slope of the amplifier 16 output. Changing the slope pad 18 value using interchangeable plug-in attenuation circuits with different attenuation values fine tunes and adjusts the characteristics of the equalizer circuit 6. The gain or signal level of amplifier 16 output is adjusted by changing the pad circuit 12 or gain pad as in the FIG. 2 circuit.

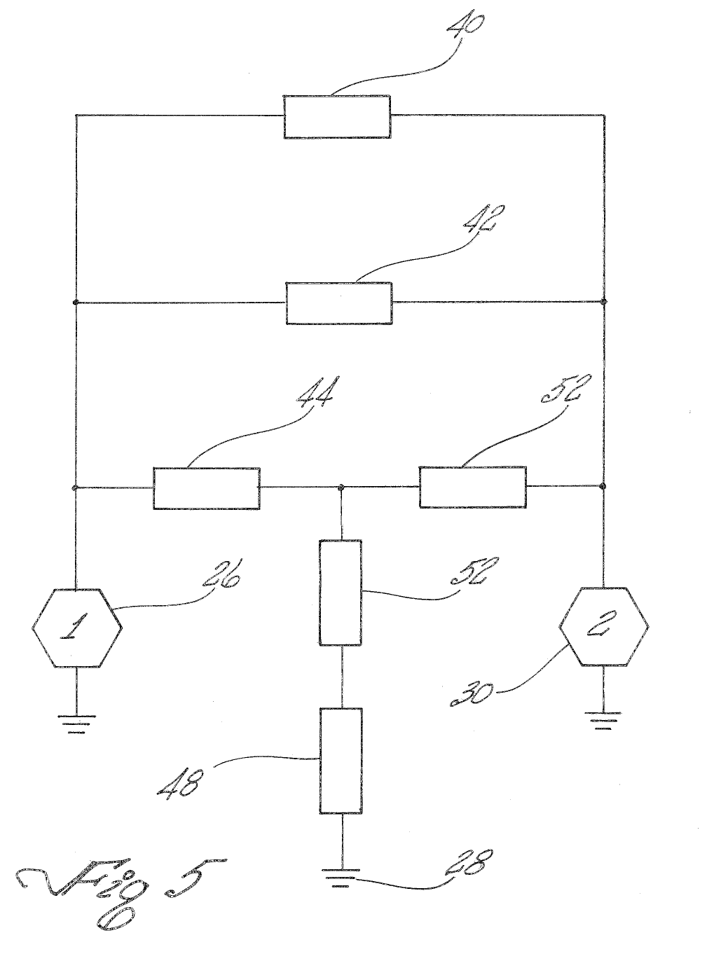

In FIG. 4, the input signal is applied to the input pin 20 of the pad circuit or gain pad 12. Output pin 24 of the gain pad connects to the pad controlled equalizer 6. The pad controlled equalizer 6 comprises slope pad 18 and an equalizer circuit 14. The equalizer circuit 14 includes capacitor 32 that connects in series with inductor 34. The inductor in turn connects to another capacitor 36.

The output pin 30 of slope pad 18 and capacitor 36 each connect to transformer 38 (FIG. 4). The output pin 24 of gain pad 12 connects to input pin 26 of slope pad 18 and capacitor 32. The ground pin 28 of the slope pad 18 connects to the reference ground. The specific values for these components 32, 34, 36 and 38 depend on the application and the attenuation of the cable transmission network for which the equalizer is compensating. Amplifier 16 amplifies the output of the pad controlled equalizer 6 taken from the connection between capacitor 36 and transformer 38.

In the present invention, gain pad 12 and slope pad 18 are wide range thermal pads. They vary their attenuation in response to changes in ambient temperature. Technically, they vary attenuation based upon temperature changes of the pads, which approximates ambient temperature and cable temperature. The exemplary embodiment accomplishes this while maintaining or approximating a 75Ω return loss match. These thermal pads automatically vary their attenuation to adjust the equalization and provide the necessary compensation for changes in the attenuation of the cable transmission network based upon changes in temperature. Thus, they stimulate automatic gain control (“AGC”) for the effects of temperature.

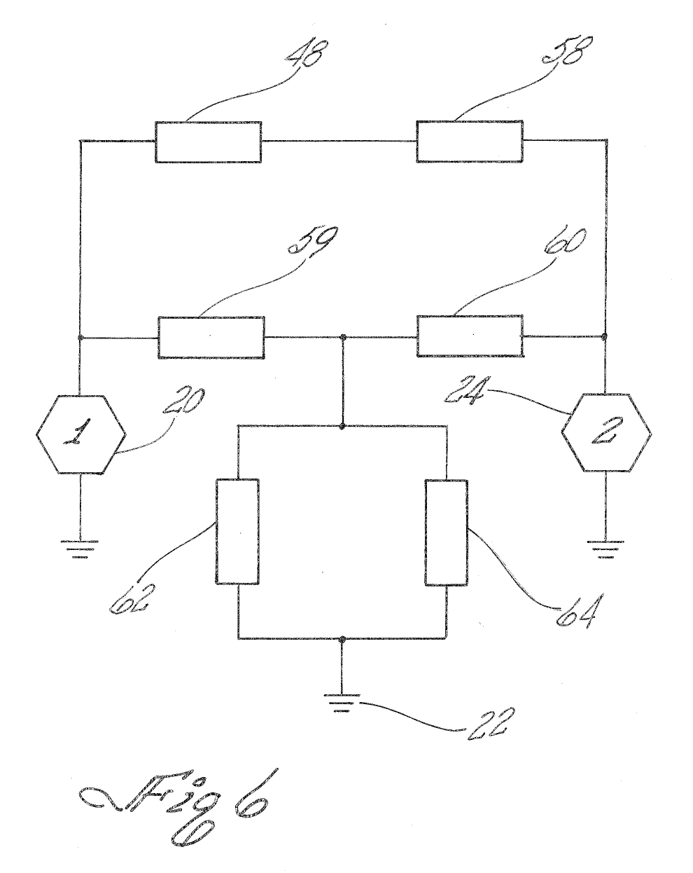

FIG. 5 shows a schematic diagram of the slope pad 18 for use in the exemplary embodiment. The output pin 24 from the gain pad 12 (FIG. 4) connects to the input pin 26 of slope pad 18 (FIG. 5). Resistive elements in the slope pad's circuit attenuate the input signal to produce the output signal at the output pin 30. The ground pin 28 connects to the reference ground.

In the exemplary embodiment, slope pad 18 uses two thermal resistors 42 and 48. A thermal resistor is a semiconductor device made of materials whose resistance changes as a function of temperature. The first resistor 42 is a 100Ω negative coefficient thermal resistor. The second resistor 48 is a 56Ω positive coefficient thermal resistor. The input pin 26 (FIG. 5) connects to the negative coefficient thermal resistor 42 and two other resistors 40 and 44. Resistor 44 connects to the ground pin 28 through a series arrangement of another resistor 50 and the positive coefficient thermal resistor 48. Resistor 44 also connects to another resistor 52.

The output pin 30 connects to the negative coefficient resistor 42 and two other resistors 40 and 52. In the exemplary embodiment, the attenuation of slope pad 18 increases when ambient temperature increases and decreases when ambient temperature decreases. The circuit of the exemplary embodiment shown in FIG. 5 results in an attenuation of slope pad 18 that varies ±3 dB over temperatures from −40° C. to 10° C. (−40° F. to 50° F.).

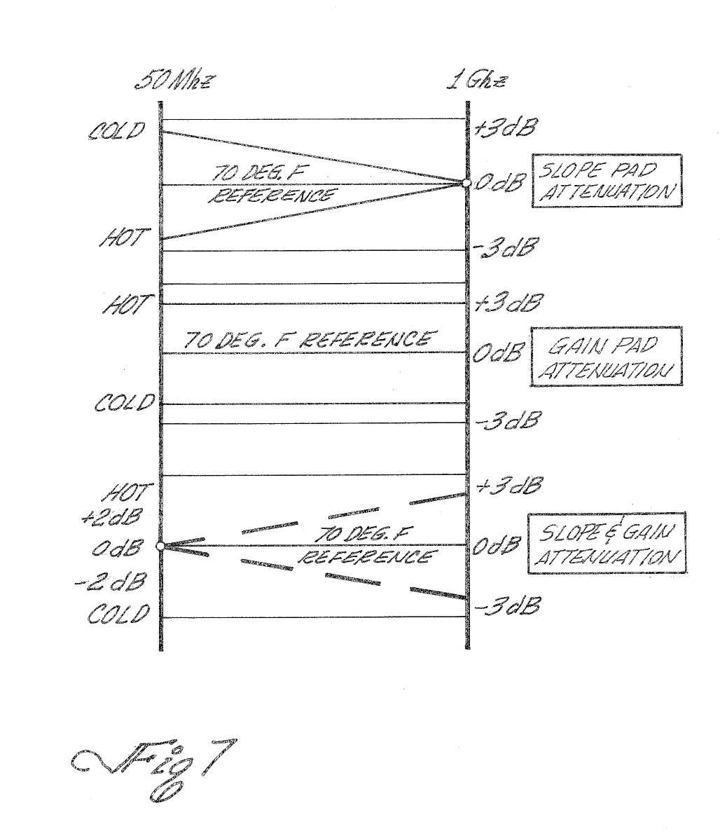

FIG. 6 shows a schematic diagram of gain pad 12 (FIG. 4) for use in the exemplary embodiment. The input signal is applied to the input pin 20 of the gain pad. The circuit's resistors attenuate the input signal to produce the output signal at the output pin 24 of the gain pad. The ground pin 22 connects to the reference ground.

In the exemplary embodiment, gain pad 12 uses two thermal resistors 54 and 64. The first resistor 54 is a 56Ω positive coefficient thermal resistor. The second resistor 64 is a 100Ω negative coefficient thermal resistor. The input pin 20 connects to the positive coefficient thermal resistor 54 and another resistor 58. The positive coefficient resistor 54 connects to another resistor 56 which connects to the output pin 22. The other resistor connects to the negative coefficient resistor 64 connected in parallel to the ground with another resistor 62, and is also connected to a third resistor 60, which connects to the output 22.

In the exemplary embodiment, attenuation of gain pad 12 decreases when ambient temperature increase, and increases when ambient temperature decreases. The circuit of the exemplary embodiment results in a gain pad 12 that varies ±3 dB over the temperature from −40° C. to 10° C. (−40° F. to 50° F.).

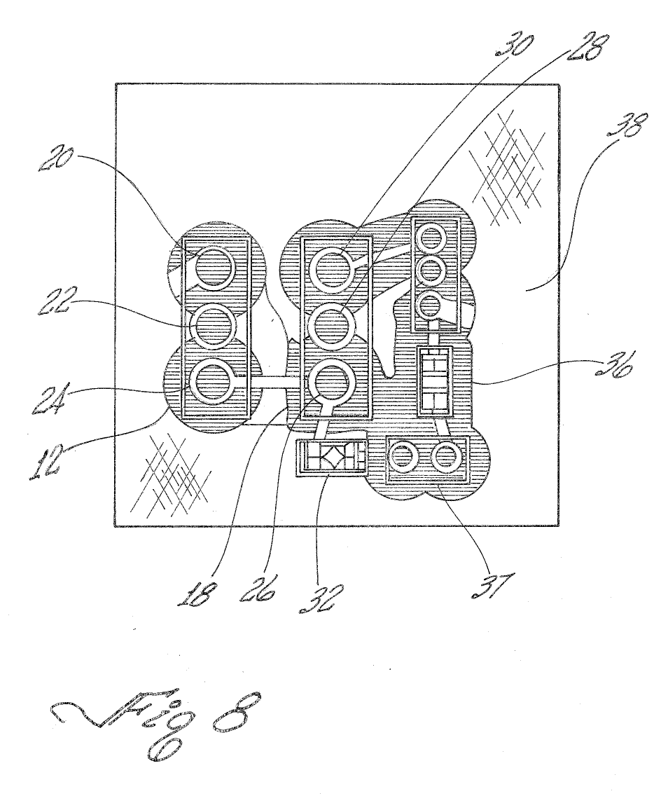

Thus, whereas attenuation of slope pad 18 increases when ambient temperature increases, and the attenuation decreases when ambient temperature also decreases, attenuation of the gain pad 12 proceeds in the opposite direction. This configuration is intended to achieve a flat response over temperature for the entire network. For example, when temperature increases, the attenuation of the cable increases non-linearly. The attenuation increases as temperature increases and as frequency increases. In the exemplary embodiment, the equalizer 14 consisting of various components 32, 34, 36, 38 and the slope pad 18 compensate for the cable attenuation by providing an inverse response curve that is opposite to cable response over the entire bandwidth. The gain pad 12 decreases its attenuation as temperature increases thereby reducing the insertion loss of the pad. When the frequency response of the gain pad 12 and the equalizer 14 are combined, the resulting response curve is opposite the response curve of the preceding cable network, which results in flat response over temperature across the entire network. This concept is illustrated in FIG. 7 below.

FIG. 7 shows a Bode gain plot for the exemplary embodiment using a temperature of 70° F. (21° C.) as a reference temperature (0 dB) plotted against frequency. Those skilled in the art appreciate that gain is the opposite of attenuation, and therefore a decrease in gain correlates with an increase in attenuation for the purposes of understanding FIG. 7 in light of the preceding description.

FIG. 7a shows the frequency response curve of the equalizer circuit 14 showing the effects of the slope pad 18 of the exemplary embodiment. When the temperature increases, the attenuation of the circuit increases (gain decreases). The slope of the gain is determined by the components 32, 34, 36, 38 of the equalizer circuit 14. FIG. 7b shows the frequency response curve of the gain pad 12, where the attenuation decreases (gain increases) as temperature increases. FIG. 7c shows the combination of the frequency response curve of the equalizer 14 and slope pad 18 with the response curve of the gain pad 14. The resulting response curve shows a non-linear decrease in attenuation (increase in gain) as temperature increases, which when combined with the non-linear increase in attenuation of the cable network as temperature increases, will yield a flat frequency response over temperature.

As with all automatic gain control (AGC) circuits, some amplifier gain reduction at ambient temperature is necessary to achieve automatic gain control over the full temperature range. For the purposes of illustration, FIG. 7 uses a reference temperature of 70° F. (21° C.). The circuit of the exemplary embodiment results in an overall signal loss of approximately 4-6 dB at that temperature. This is because there must be sufficient reserve gain available when the module is at the highest temperature. The combination of a thermally controlled pad as shown in FIG. 6 at the gain pad location 12 and a thermally controlled pad as shown in FIG. 5 at the slope pad location 18 controls response tilt from 50 MHz to 1 GHz. This thermal compensation performs like an analog or digital channel controlled AGC, alternatively referred to as Bode slope control, where a reference channel is filtered out of the signal and monitored for changes in amplitude. The Bode slope control monitors signal level of the reference channel through the use of op-amp comparators, and then varies the DC voltage to a combination of pin diodes within a pin diode controlled equalizer circuit to compensate for changes in temperature.

Thermal AGC lacks the accuracy or the range of a Bode slope control, but does provide compensation for a portion of the dB changes due to temperature. The combination of thermal slope and gain pads works together to simulate the typical Bode slope control. A typical Bode DC controlled slope control can compensate for a range of 8 dB of cable length change due to temperature swings. The combined thermal pads in the exemplary embodiment compensates for a range of 6 dB of cable length. This range can be changed by substituting other thermal resistors that exhibit the required resistance tracking and change over temperature. The present invention tracks temperature using only passive components. While the present invention requires less power because it uses passive components, it does not function as a true active AGC circuit as the Bode slope control design does. A range of 8 dB can be used in the Bode slope control because there is no risk for overcompensation. There is a greater possibility of tracking error in the present invention because it compensates based upon changes in the ambient temperature whereas active designs monitor changes in the signal. Therefore, there is a greater risk of inaccuracy and overcompensation in the present invention. However, in most cases a 6 dB range is sufficient.

FIG. 8 shows a PCB layout of a thermal pad controlled equalizer, which reflects the interconnections shown on the schematic of FIG. 4. The gain pad 12 and slope pad 18 can be changed to adjust the slope and gain of the amplifier depending on the needs of the cable transmission network at that amplifier location. In the exemplary embodiment of the present invention, the thermal pads adjust the amplifier output to compensate for changes in the transmission network resulting from changes in ambient temperature.

I claim:

1. A method for controlling the slope and the gain of the output of a pad adjustable amplifier for use in a cable transmission network in response to changes in ambient temperature comprising:
selecting a first thermal plug-in attenuation circuit to adjust the gain of the pad adjustable amplifier, the first thermal plug-in attenuation circuit varying its attenuation in response to a change in ambient temperature;
selecting a second thermal plug-in attenuation circuit to adjust the slope of the pad adjustable amplifier, the second thermal plug-in attenuation circuit varying its attenuation in response to a change in ambient temperature, wherein the second thermal plug-in attenuation circuit varies the attenuation generally inverse to the adjustment of the first thermal plug-in attenuation circuit in response to ambient temperature change; and
plugging the plug-in attenuation circuits into the pad adjustable amplifier to produce the desired performance.

2. A thermal pad controlled equalization circuit equalizing the strength of signals in a cable transmission system comprising:
an equalization circuit;
a first plug-in attenuation component having a first attenuation value, the first attenuation value increasing in response to decreases in ambient temperature, the first plug-in attenuation component being adapted to plug into the equalization circuit; and
a second plug-in attenuation component having a second attenuation value, the second attenuation value decreasing in response to increases in ambient temperature, the second plug-in attenuation component being adapted to plug into the equalization circuit.

3. A controlled equalizer for use in an amplifier for a cable transmission system, the amplifier having a gain and a slope and comprising:
first attenuation means attachable to the equalizer for adjusting the gain of the amplifier in response to changes in ambient temperature;
second attenuation means attachable to the equalizer for adjusting the slope of the amplifier in response to changes in ambient temperature.
